(19) United States
(12) Patent Application Publication
(10) Pub. No.: US 2001/0004510 A1
(43) Pub. Date: Jun. 21, 2001

(54) Refractory bilayer resist materials for lithography using highly attenuated radiation

(76) Inventor: David R. Wheeler, Albuquerque, MN (US)

Correspondence Address: Sandia Labs, Patents MS 9031, P.O. Box 969, Livermore, CA, 94551-0969, US

(21) Appl. No.: 09/741,450

(22) Filed: Dec. 19, 2000

Related U.S. Application Data
(63) Continuation-in-part of application No. 09/212,062, filed on Dec. 15, 1998, now abandoned.

(51) Int. Cl. G03F 7/038

(52) U.S. Cl. 430/270.1; 430/286.1; 585/361; 430/197; 430/927; 526/268; 526/279; 556/136

(57) ABSTRACT

Novel silicon-containing polymer compounds, based on cyclic olefins. These polymer compounds can be used as photoresist materials and because they are transparent to radiation in the spectral range from 193 to 13 nm, which is highly energetic and strongly attenuated, are particularly advantageous as refractory bilayer photoresist materials for semiconductor wafer patterning processes that employ deep ultraviolet (DUV) and extreme ultraviolet (EUV) radiation.

### STATEMENT OF GOVERNMENT INTEREST

This invention was made with Government support under contract no. DE-AC04-94AL85000 awarded by the U.S. Department of Energy to Sandia Corporation. The Government has certain rights in the invention.

### CROSS-REFERENCE TO RELATED APPLICATIONS

Not applicable.

### BACKGROUND OF THE INVENTION

This invention pertains generally to novel polymers useful for thin layer imaging microlithography and particularly to cyclic olefin polymers that are useful for deep ultraviolet (DUV) and extreme ultraviolet (EUV) lithography, i.e., lithography employing radiation in the range of about 193 to 13 nm.

Integrated circuits are typically manufactured using lithographic processes. Energy (generally electromagnetic radiation, i.e., light) is caused to interact selectively with an energy sensitive resist material deposited onto a substrate in such a way that a pattern or image is produced on the resist material. The resist material is developed and the pattern is transferred by etching onto the substrate.

When a single layer of resist material is applied over a nonplanar substrate pattern, light scattering by the resist material and substrate, as well as the inability of DUV or EUV radiation to completely penetrate and uniformly expose the resist material can result in errors in the defined lithographic pattern. The topography of the substrate surface may also adversely affect the ability of the lithographic process to define features on the substrate. Consequently, surface imaging lithographic processes have been developed that do not require that the resist material be exposed throughout its entire thickness. These processes are referred to as surface imaging processes, or thin layer imaging (TLI), because they define features only in the near surface region of the resist. A pattern (or aerial image) is transferred into a thin top layer which is subsequently developed normally and then used to transfer the pattern into the thicker underlying organic layer that acts as the planarizing or device processing layer. By providing a planarizing layer disposed between the surface of the substrate and the imaging layer, it is possible to deposit a uniform imaging layer having minimum thickness, thereby reducing problems associated with variations in depth of focus (DOF).

While surface imaging is needed for patterning advanced integrated circuits using highly attenuated radiation, the technology may also offer advantages for applications having narrow design rules, where standard lithographic processes are difficult due to severe wafer topography, or radiation reflection or DOF limitations are present since imaging just the surface of the resist relaxes DOF requirements. High numerical aperture (i.e., comparatively small) steppers, while capable of printing smaller features at a given wavelength, often have small DOF and this can preclude focused exposure through the thickness of the film

One TLI approach to lithography using 193, 157 and 13.4 nm radiation, i.e., radiation which is strongly attenuated by photoresist materials, is the refractory bilayer scheme. Here, a planarizing layer, that can be an organic polymer, is spin-coated and fusion-baked onto a substrate. A subsequent coating step deposits a thin layer (typically ≈100 nm thick) of a solution-developable, silicon-containing imaging layer onto the planarizing layer. A latent image, defined by the sum of exposed and unexposed areas on the imaging layer, can be transferred onto the imaging layer by exposing certain portions of the polymeric resist material to radiation. Exposure can take place either by direct imaging through a mask or by radiation being reflected from a mask or reticle. Radiation incident upon the silylated imaging layer will generate a base-soluble group on the resist polymer rendering the exposed polymer itself base-soluble. The pattern transfer step relies on the known oxygen etch rate difference between organosilicon and non-silicon containing portions of the patterned organic photoresist materials. Generally, at least 10% by weight of a refractory element such as silicon is needed to accomplish a satisfactory etch rate selectivity between the layers.

It is particularly desirable to have a refractory bilayer photoresist material that can be used for both DUV (193 and 157 nm) and EUV (13.4 nm) lithography. However, the nature of the absorption of radiation in the DUV and EUV regions of the spectrum is not the same which makes the selection of a common photoresist material difficult.

For lithography in the EUV region of the spectrum (13.4 nm), absorption of radiation is atomistic in nature. Thus, the presence of oxygen atoms, which absorb radiation strongly in the EUV region, should be minimized.

For lithography in the DUV region of the spectrum (193 and 157 nm), absorption of radiation is by excitation of valence shell electrons thus, prediction of the absorption characteristics of photoresist materials is difficult. However, it is known that for 193 nm lithography it is desirable to avoid all aromatic or unsaturated carbon linkages. While oxygen can be tolerated, from the point of view of absorption, large quantities are to be avoided because of adverse effects on etch rate of photoresist materials.

It is known in the art, that polymers made from cyclic olefins are transparent to 193 nm radiation and have been used as single layer photoresist materials in this spectral region. It would be advantageous to employ cyclic olefin materials also for 157 and 13.4 nm lithography. However, single layer photoresist materials would be difficult to implement because of the rapid attenuation of these wavelengths. While the obvious solution to attenuation of 157 and 13.4 nm radiation would be to use thinner layers of photoresist material, layers of photoresist materials thinner than about 150-200 nm are prone to pin holes and density fluctuations arising from nonuniform coating.

In addition to transparency in the desired DUV and EUV spectral regions, it is preferred that cyclic olefin photoresist materials possess several additional features that make them useful for bilayer applications, namely:

1. Proper adhesion to the lower planarizing/pattern transfer layer.

2. Low level of pinhole defects in the thin photoresist layer.

3. Satisfactory working depth, dark erosion rate and etch selectivity in a plasma to accomplish pattern transfer.

4. Achieve sensitivities of from 5-20 mJ/cm² depending upon radiation wavelength.

5. Compatible with standard TMAH developers.

What is proposed is to provide silicon containing cyclic olefin polymers derived from norborane-type monomers that, while maintaining desirable transparency characteristics, could be used as a refractory bilayer material and thus, suitable for lithographic applications over the range of 193 to 13.4 nm.

### SUMMARY OF THE INVENTION

The present invention discloses silicon-containing cyclic olefin-based materials that are suitable for use as refractory bilayer photoresist materials for lithographic applications in the DUV (193 and 157 nm) and EUV (13.4 nm) regions of the spectrum and additionally, possesses the desirable features of adhesion and spectral sensitivity.

### DETAILED DESCRIPTION OF THE INVENTION

The present invention is drawn to novel silicon-containing polymer compounds, based on cyclic olefins, that can be used as photoresist materials and are particularly advantageous as refractory bilayer photoresist materials for semiconductor wafer patterning processes that employ highly energetic, strongly attenuated radiation such as deep ultraviolet (DUV) radiation in the range 157 to 193 nm and extreme ultraviolet (EUV) radiation at about 13.4 nm. These novel cyclic olefin polymers are derived from norbornane-type monomers and can be characterized by the general structural formula

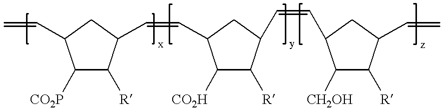

wherein P can be alkyl, tertiary alkyl, acetal, or lactone; R′ can be (CH₃)₃Si, Si₂(CH₃)₅, Si(SiCH₃)₃, and Si(OSiCH₃)₃; x is ≧1 and is chosen such that the unprotected polymer is soluble in tetramethyl ammonium hydroxide (TMAH) and the protected polymer is insoluble in TMAH; and y and z are chosen to impart to the polymer the desired lithographic properties of good adhesion to a substrate and proper viscosity and glass transition temperature (T_{g}) to provide a low level of pinhole defects and complete coverage of a planarizing layer.

It is well known in the art that five- and six-membered ring compounds, and particularly cyclic olefins, are readily prepared by means of the Diels-Alder reaction. This versatile synthetic reaction consists in 1,4 addition of a diene to a second compound having an unsaturated carbon-carbon bond, as illustrated below for the reaction of cyclopentadiene (1a) and a substituted diene (1b).

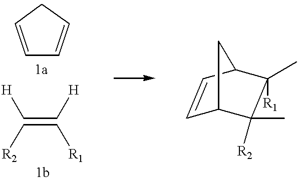

A very wide range of R1 and R2 groups are possible including silicon groups for etch resistance, carboxylic acid groups for adhesion and solubilizing groups. This class of molecules provides a very large design space for preparation of DUV and EUV photoresist materials due to the versatility of their synthesis via Diels-Alder chemistry.

Polymerization of the cyclic olefin product for use as a photoresist material can be by any of three major routes: 1) radical induced polymerization; 2) radical-like polymerization through the use of special catalysts such as, but not limited to, Pd(CH₃CN)₄(BF₄)₂; and 3) ring opening metathesis polymerization (ROMP) illustrated below.

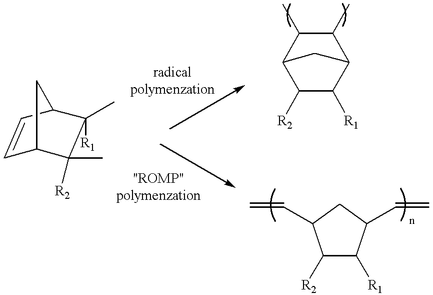

The novel cyclic olefin polymers of the present invention can be prepared using ROMP in a synthesis route such as that given below. While others of skill in the art can envision alternate synthesis methods for the preparation of the novel cyclic olefins, the method of synthesis illustrated here is simply provided to enable those skilled in the art to make and use the invention. The invention is drawn to the composition of the cyclic olefins themselves and not necessarily their method of preparation. The reaction sequence below sets forth a method for preparing a novel cyclic olefin contemplated by the present invention

A dienophile starting material 2 can be prepared by methods known to those skilled in the art (e.g. Zargarian, D. and Alper, H. Organometallics, 12(3), 712-24, 1993). The Diels-Alder reaction between dienophile 2 (which must be in its acid form to allow back extraction of the product 3 into an aqueous base to separate it from the cyclopentadiene dimer) and cyclopentadiene is performed at moderate temperature (≈60° C.) in a bomb with stirring. The reactants are allowed to react for about 12 hrs after which time the product is isolated by extraction into aqueous base (NaOH). The aqueous phase is washed with cyclohexane, acidified (1N HCl), and extracted with Et₂O. The ether extract is dried over magnesium sulfate, filtered, and the ether is removed under vacuum at 70-120° C. The distillate was fractionally distilled and product 3, which is a mixture of isomers, recovered at 105-110° C. The ratio of isomers formed is ≈1:3 depending upon the exact reaction conditions. The identity of each isomer has not been determined, however, the mix of isomers is used as reactants for the second step.

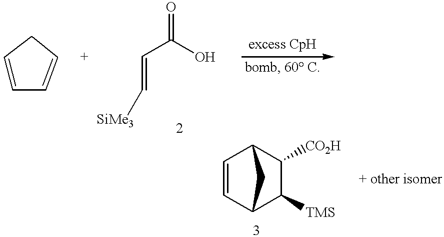

Because most ROMP catalysts do not tolerate active protons it is necessary that the carboxylic acid functionality on product 3 be blocked. The trimethylsilyl (TMS) derivative can be made by standard methods. By way of example, reaction of hexamethyldisilazane (HMDS) with 3 and a catalyst trimethylchlorosilane in tetrahydrofuran (THF) followed by filtration and distillation yielded the TMS protected carboxylate 4 in almost quantitative yield.

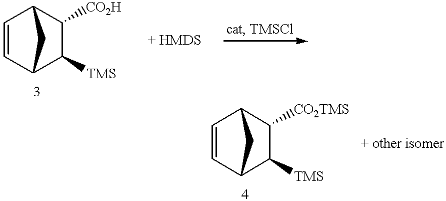

The second monomer reactant required for the ROMP polymerization step can be prepared by using the t-butyl ester as a blocking group protecting the carboxylate. Here, the mix of isomers 3 is reacted under basic conditions using excess sodium hydride and tosyl chloride followed by reaction with excess t-butyl alcohol and the potassium salt (KOtBu) to produce the t-butyl ester protected isomer 5.

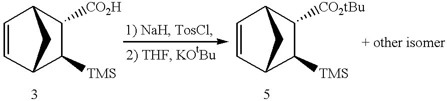

Copolymerization was carried out by reacting 5 equivalents of the TMS protected carboxylate monomer 4 with 4 equivalents of the t-butyl ester protected monomer 5 in benzene using ≈1/50 equivalents of the ROMP catalyst 2,6-diisopropylphenylimidoneophylidene molybdenum bis(t-butoxide) in benzene in a Schlenk tube. The mixture was allowed to react for about 12 hrs with stirring. The polymer 6 was isolated by precipitation into MeOH followed by drying yielding a tan powder.

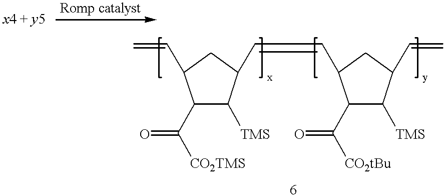

The dried polymer was deprotected with a mixture of MeOH/THF/H₂O in quantitative yield. This solution was then precipitated into water followed by drying under vacuum to give an almost white powder. Light scattering gpc gave Mw=50.6k, Mn=33.8 and Mw/Mn=1.5.

Modifications such as replacement of the TMS group by moieties such as pentamethyldisilyl as well as replacement of carboxylic acid groups by CH₂OH as well as incorporation of non-cyclic olefins, such as maleic anhydride, to improve the properties of the photoresist material such as adhesion, dissolution in developers, and sensitivity to radiation are contemplated by this invention.

Because polymer 6 contains some unsaturated bonds it is not ideally suited as a photoresist material for 193 nm lithography. Consequently, the inventors have devised a scheme for hydrogenating polymer 6 to eliminate unsaturation. In an inert atmosphere environment, 3.75 g of polymer 6 was dissolved in 50 ml of tetrahydrofuran. To this solution was added Crabtree's catalyst (triscyclohexylphosphine-1,5-cyclooctadiene(pyridine)iridium (I) hexafluorophosphate. Following addition of the catalyst, the solution was placed in a high pressure Parr reactor, pressurized with hydrogen to 1000 psi, and heated to 70° C. with stirring. After cooling and venting the Parr reactor, the hydrogenated polymer was isolated by precipitation in 4 liters of water. NMR analysis of the dried polymer product indicated about 60% conversion to the hydrogenated form shown below

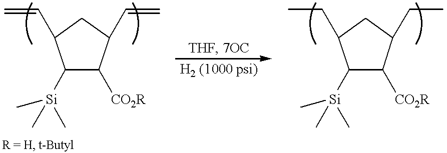

While the invention has now been described in terms of certain preferred embodiments, and exemplified with respect thereto, those skilled in the art will appreciate that various modifications, changes, substitutions, and omissions can be made without departing from the scope of the present invention which is limited only by the following claims.

I claim:

1. A photoresist material consisting of a polymeric material characterized by the general structural formula: 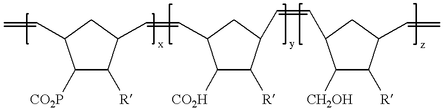
wherein P includes alkyl, tertiary alkyl, acetal or lactone; R′ includes (CH₃)₃Si, Si₂(CH₃)₅, Si(SiCH₃)₃, and Si(OSiCH₃)₃; x is ≧1 and is chosen such that the unprotected polymer is soluble in tetramethyl ammonium hydroxide (TMAH) and the protected polymer is insoluble in TMAH; and y and z are chosen to provide the desired lithographic properties of good adhesion to a substrate and proper viscosity to provide a low level of pinhole defects and coverage of the substrate.

2. The photoresist material of claim 1, wherein P is t-butyl, R′ is (CH₃)₃Si, and z is 0.

3. A compound having the formula: 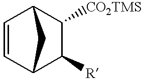
wherein R′ includes (CH₃)₃Si, Si₂(CH₃)₅, Si(SiCH₃)₃, and Si(OSiCH₃)₃.

4. A photoresist material consisting of a polymeric material having the general structural formula 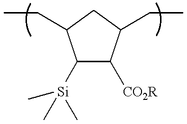
wherein R is H or t-butyl.
